(19) United States
(12) Patent Application Publication
(10) Pub. No.: US 2025/0046728 A1
(43) Pub. Date: Feb. 6, 2025

(54) SEMICONDUCTOR PACKAGE

(71) Applicant: Samsung Electronics Co., Ltd., Suwon-si (KR)

(72) Inventors: Dongwon KANG, Suwon-si (KR); Hongwon KIM, Suwon-si (KR); Changyeon SONG, Suwon-si (KR); Sunguk LEE, Suwon-si (KR); Jae-Ean LEE, Suwon-si (KR)

(73) Assignee: Samsung Electronics Co., Ltd., Suwon-si (KR)

(21) Appl. No.: 18/429,538

(22) Filed: Feb. 1, 2024

(30) Foreign Application Priority Data
Aug. 2, 2023 (KR) 10-2023-0101087

(51) Int. Cl. H01L 23/544; H01L 23/00; H01L 23/498

(52) U.S. Cl. CPC H01L 23/544; H01L 23/49822; H01L 23/49833; H01L 23/49838; H01L 23/49866; H01L 24/16; H01L 2223/54406; H01L 2224/16227; H01L 2224/16238; H01L 2924/15153; H01L 2924/15174; H01L 2924/16251; H01L 2924/182

(57) ABSTRACT

A semiconductor package may include a semiconductor chip and an upper redistribution layer including a marking structure on the semiconductor chip, an upper insulating layer surrounding the marking structure, and an outer insulating layer on the upper insulating layer, wherein the marking structure may include a lower marking pattern, a marking via on the lower marking pattern, and an upper marking pattern on the marking via, the upper marking pattern may include a first conductive pattern on the marking via and a second conductive pattern on the first conductive pattern, and the second conductive pattern may be exposed by a trench defined by the outer insulating layer.

### CROSS-REFERENCE TO RELATED APPLICATIONS

This U.S. non-provisional patent application claims priority under 35 U.S.C. § 119 to Korean Patent Application No. 10-2023-0101087, filed on Aug. 2, 2023, in the Korean Intellectual Property Office, the entire contents of which are hereby incorporated by reference.

### BACKGROUND OF THE INVENTION

The inventive concepts relate to semiconductor packages, and more particularly, to semiconductor packages including a marking structure.

Integrated circuit chips are typically provided with a semiconductor package so as to be suitably applied to circuit boards of electronic products or otherwise combined within an electronic system. In a general semiconductor package, an integrated circuit chip (or a semiconductor chip) may be mounted on a printed circuit board (PCB) and may be electrically connected to the PCB through bonding wires or bumps. Various researches for improving reliability of semiconductor packages have been conducted with the development of an electronic industry.

### SUMMARY

Objects of the inventive concepts are to provide semiconductor packages with improved visibility, electrical characteristics, and durability.

A semiconductor package according to some example embodiments of the inventive concepts may include a semiconductor chip and an upper redistribution layer including a marking structure on the semiconductor chip, an upper insulating layer surrounding the marking structure, and an outer insulating layer on the upper insulating layer, the marking structure may include a lower marking pattern, a marking via on the lower marking pattern, and an upper marking pattern on the marking via, the upper marking pattern may include a first conductive pattern on the marking via and a second conductive pattern on the first conductive pattern, and the second conductive pattern may be exposed by a trench defined by the outer insulating layer.

A semiconductor package according to some example embodiments of the inventive concepts may include a semiconductor chip and an upper redistribution layer including a marking structure on the semiconductor chip, an upper insulating layer surrounding the marking structure, and an outer insulating layer on the upper insulating layer, the marking structure may include a first conductive pattern, a second conductive pattern on the first conductive pattern, and a third conductive pattern on the second conductive pattern, an upper surface of the second conductive pattern may be exposed by a trench defined by the outer insulating layer, and the first conductive pattern and the second conductive pattern may include different materials.

A semiconductor package according to some example embodiments of the inventive concepts may include a lower redistribution layer, a semiconductor chip on the lower redistribution layer, a core layer surrounding the semiconductor chip on the lower redistribution layer and including a core via, and an upper redistribution substrate on the semiconductor chip, the upper redistribution substrate may include a marking structure overlapping the semiconductor chip, an upper insulating layer surrounding the marking structure, a dummy marking pattern exposed through an outer wall of the upper insulating layer, and an outer insulating layer on the marking structure, the upper insulating layer, and the dummy marking pattern, the marking structure includes a lower marking pattern, a marking via on the lower marking pattern, and an upper marking pattern on the marking via, and a level of the dummy marking pattern is a same level as a level of the upper marking pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view of a semiconductor package according to some example embodiments.

FIG. 1B is a cross-sectional view taken along line A-A′ in FIG. 1A.

FIG. 1C is an enlarged view of region ‘E1’ in FIG. 1B.

FIG. 1D is an enlarged view of region ‘E2’ in FIG. 1B.

FIGS. 2A, 2B, 2C, 2D, 2E, and 2F are cross-sectional views for explaining a method of manufacturing a semiconductor package according to some example embodiments.

FIG. 3 is a cross-sectional view of a semiconductor package according to some example embodiments.

FIG. 4 is a cross-sectional view of a semiconductor package according to some example embodiments.

FIG. 5 is a cross-sectional view of a semiconductor package according to some example embodiments.

### DETAILED DESCRIPTION

Hereinafter, semiconductor devices and manufacturing methods thereof according to example embodiments of the inventive concepts will be described in detail with reference to the drawings.

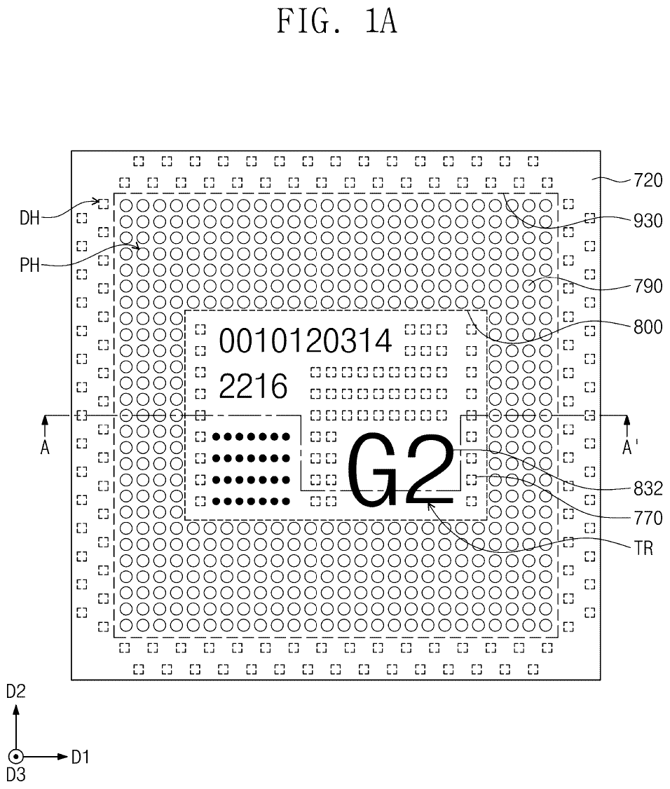

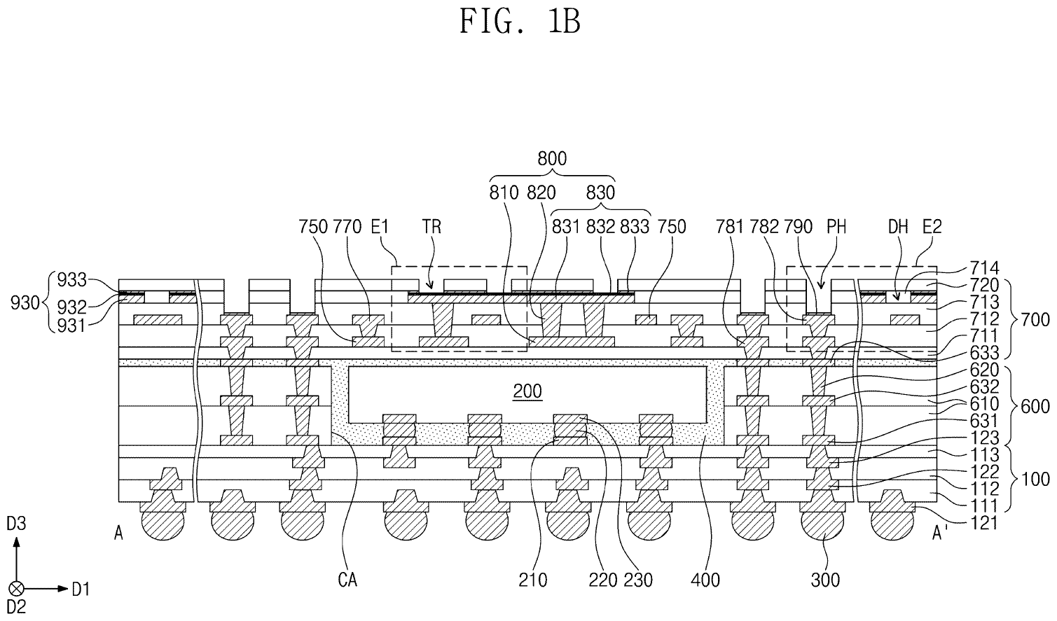

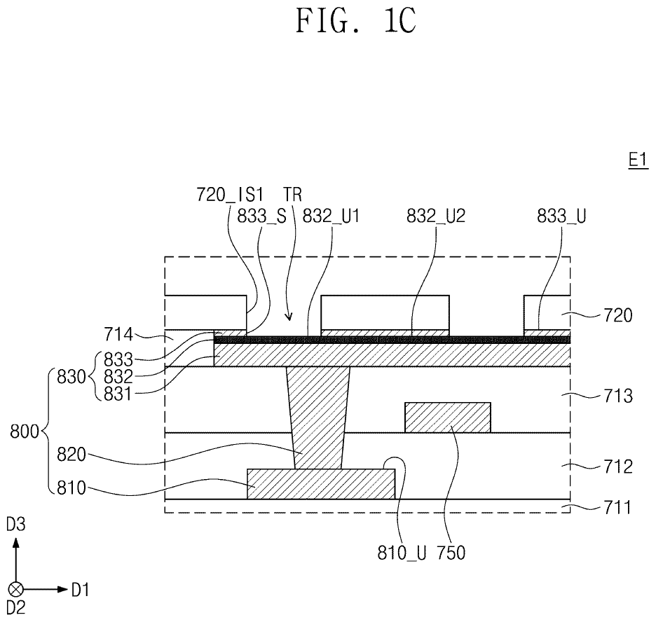

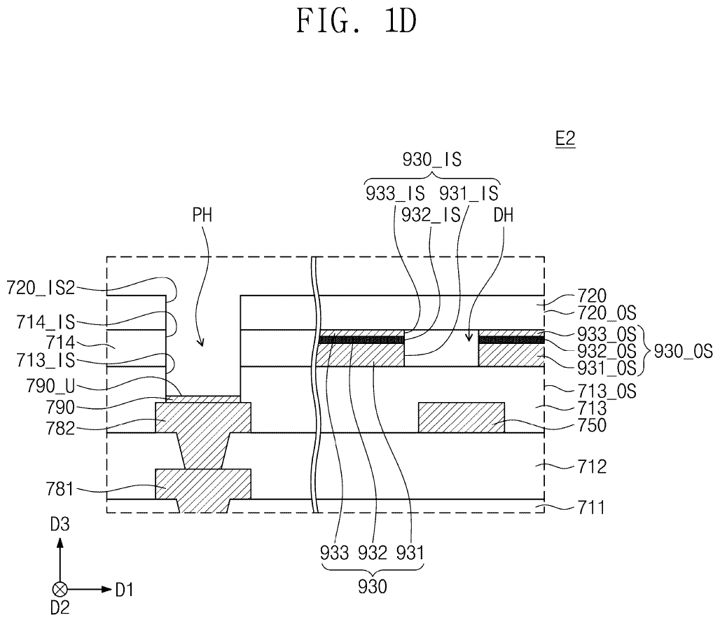

FIG. 1A is a plan view of a semiconductor package according to some example embodiments. FIG. 1B is a cross-sectional view taken along line A-A′ in FIG. 1A. FIG. 1C is an enlarged view of region ‘E1’ in FIG. 1B. FIG. 1D is an enlarged view of region ‘E2’ in FIG. 1B.

Referring to FIGS. 1A, 1B, 1C, and 1D, a semiconductor package may include a lower redistribution layer 100, a semiconductor chip 200, bumps 220, solder balls 300, a molding layer 400, a connection substrate 600, and an upper redistribution layer 700.

The lower redistribution layer 100 may include lower insulating layers 111, 112, and 113 and lower patterns 121, 122, and 123. The lower redistribution layer 100 may be provided on the solder ball 300.

The lower insulating layers 111, 112, and 113 may have the shape of a plate extending along a plane defined by a first direction D1 and a second direction D2. The first direction D1 and the second direction D2 may intersect each other. For example, the first direction D1 and the second direction D2 may be horizontal directions orthogonal to each other.

The lower insulating layers 111, 112, and 113 may include first to third lower insulating layers 111, 112, and 113. The number of lower insulating layers 111, 112, and 123 may not be limited thereto. For example, the number of lower insulating layers 111, 112, and 123 may be 2 or less, or 4 or more.

The first to third lower insulating layers 111, 112, and 113 may be sequentially stacked in a third direction D3. The third direction D3 may intersect the first direction D1 and the second direction D2. For example, the third direction D3 may be a vertical direction orthogonal to the first direction D1 and the second direction D2. The second lower insulating layer 112 may be disposed on the first lower insulating layer 111. The third lower insulating layer 113 may be disposed on the second lower insulating layer 112.

The first to third lower insulating layers 111, 112, and 113 may include an insulating material. The first to third lower insulating layers 111, 112, and 113 may include an organic material such as a photo-imageable dielectric (PID) material. The photo-imageable dielectric material may include, for example, at least one of photosensitive polyimide, polybenzoxazole, phenol-based polymer, and benzocyclobutene-based polymer.

The lower patterns 121, 122, and 133 may be conductive patterns disposed inside the lower insulating layers 111, 112, and 113. The lower patterns 121, 122, and 133 may be surrounded by lower insulating layers 111, 112, and 113. The lower patterns 121, 122, and 133 may include first to third lower patterns 121, 122, and 123. The second lower pattern 122 may be disposed on the first lower pattern 121. The third lower pattern 123 may be disposed on the second lower pattern 122. The first lower pattern 121 may be disposed within the first lower insulating layer 111. The second lower pattern 122 may be disposed within the second lower insulating layer 112. The third lower pattern 123 may be disposed within the third lower insulating layer 113.

The first to third lower patterns 121, 122, and 133 may include a line portion for horizontal connection and a via portion for vertical connection on the line portion. The first to third lower patterns 121, 122, and 133 may include a conductive material. As an example, the first to third lower patterns 121, 122, and 133 may include copper (Cu) or the like.

The first lower patterns 121 may be conductive patterns exposed below the lower redistribution layer 100. The first lower patterns 121 may be exposed through the first lower insulating layer 111. The via portion of the first lower pattern 121 may be surrounded by the first lower insulating layer 111. The first lower pattern 121 may be connected to the second lower pattern 122.

The line portion of the second lower pattern 122 may be surrounded by the first lower insulating layer 111. The via portion of the second lower pattern 122 may be surrounded by the second lower insulating layer 112. The second lower patterns 122 may electrically connect the first lower pattern 121 and the third lower pattern 123. The second lower pattern 122 may be connected to the third lower pattern 123;

The third lower patterns 123 may be conductive patterns exposed above the lower redistribution layer 100. The third lower patterns 123 may be exposed through the third lower insulating layer 113. The line portion of the third lower pattern 123 may be surrounded by the second lower insulating layer 112. The via portion of the third lower pattern 123 may be surrounded by the third lower insulating layer 113.

The semiconductor package may further include lower pads 210. The lower pads 210 may be disposed on the third lower insulating layer 113 of the lower redistribution layer 100. The lower pad 210 may be connected to the third lower pattern 123. The lower pad 210 may include a conductive material.

Solder balls 300 may be provided on the lower surface of the lower redistribution layer 100. The solder ball 300 may be in contact with a lower surface of the first lower pattern 121. The solder ball 300 may include a conductive material.

The semiconductor chip 200 may be mounted on an upper surface of the lower redistribution layer 100. The semiconductor chip 200 may include a semiconductor substrate. As an example, the semiconductor substrate may include silicon, germanium, silicon-germanium, gallium-phosphorus, or gallium-arsenide. In some example embodiments, the semiconductor chip 200 may include a silicon-on-insulator (SOI) substrate or a germanium-on-insulator (GOI) substrate. In some example embodiments, the semiconductor chip 200 may be any one of a logic chip, a buffer chip, and a memory chip. The number of semiconductor chips 200 may not be limited thereto. In some example embodiments, the semiconductor chip 200 may include a plurality of semiconductor chips.

The semiconductor chip 200 may include chip pads 230. The chip pad 230 may be electrically connected to the lower pad 210 through the bump 220. The chip pad 230 may include a conductive material.

The bumps 220 may electrically connect the semiconductor chip 200 and the lower redistribution layer 100. The bumps 220 may be in contact with the chip pad 230 and the lower pad 210 of the semiconductor chip 200. The bump 220 may include a conductive material.

A connection substrate 600 may be provided on the lower redistribution layer 100. The connection substrate 600 may be mounted on the lower redistribution layer 100. The connection substrate 600 may extend in the first direction D1 and the second direction D2. The connection substrate 600 may be partially removed to include one core pattern when viewed in a plan view. That is, a portion of the connection substrate 600 may be removed to provide an embedding portion CA. The embedding portion CA may have an open hole shape connecting upper and lower surfaces of the connection substrate 600. Some example embodiments of the inventive concepts describe the connection substrate 600 having one core pattern, but the inventive concepts are not limited thereto. That is, the connection substrate 600 may include a plurality of core patterns spaced apart from each other when viewed in a plan view. A semiconductor chip 200 may be provided in the embedding portion CA of the connection substrate 600.

The connection substrate 600 may include a connection insulating layer 610, connection vias 620, and connection pads 631, 632, and 633.

The connection insulating layer 610 may surround the connection vias 620 and the connection pads 631, 632, and 633. An inner wall of the connection insulating layer 610 may define the embedding region CA of the connection substrate 600. The connection insulating layer 610 may include a plurality of layers.

The connection vias 620 and connection pads 631, 632, and 633 may be conductive patterns disposed within the connection insulating layer 610. The connection vias 620 and connection pads 631, 632, and 633 may be electrically connected to the lower redistribution layer 100 and the upper redistribution layer 700.

The connection via 620 may be arranged to be spaced apart from the embedding region CA. The connection via 620 may penetrate the connection insulating layer 610 to electrically connect the connection pads 630.

The connection pads 631, 632, and 633 may include first to third connection pads 631, 632, and 633. The first to third connection pads 631, 632, and 633 may be in contact with the connection vias 620.

The first connection pad 631 may be provided between the lower redistribution layer 100 and the connection via 620. The first connection pad 631 may connect the lower redistribution layer 100 and the connection via 620. The first connection pad 631 may be in contact with the third lower pattern 123 of the lower redistribution layer 100.

The second connection pad 632 may be provided between the connection vias 620. The second connection pad 632 may connect the connection vias 620.

The third connection pad 633 may be provided between the upper redistribution layer 700 and the connection via 620. The third connection pad 633 may connect the upper redistribution layer 700 and the connection via 620. The third connection pad 633 may be disposed on an upper surface of the connection insulating layer 610.

The connection insulating layer 610 may include an insulating material. For example, the connection insulating layer 610 may include silicon oxide (SiO₂) or the like. The connection via 620 and the connection pad 630 may include a conductive material. For example, the connection via 620 and the connection pad 630 may include copper (Cu) or the like.

The number of connection insulating layers 610 may not be limited thereto. For example, the number of connection insulating layers 610 may be one or three or more. In some example embodiments, the connection insulating layer 610 may be provided as one layer, and the connection via 620 may penetrate from an upper surface to a lower surface of the connection insulating layer 610. In this case, the connection pad 630 may be provided only on the upper and lower surfaces of the connection insulating layer 610.

The molding layer 400 may be provided on the lower redistribution layer 100. The molding layer 400 may cover an upper surface of the third lower insulating layer 113 of the lower redistribution layer 100. The molding layer 400 may cover the semiconductor chip 200 and the connection substrate 600. The molding layer 400 may surround the lower pads 210, bumps 220, and third connection pads 633. The molding layer 400 may cover an upper surface and sidewalls of the semiconductor chip 200. In some example embodiments, the molding layer 400 may cover a sidewall of the semiconductor chip 200 and expose an upper surface of the semiconductor chip 200. The molding layer 400 may cover an upper surface and inner wall of the connection substrate 600. In some example embodiments, the molding layer 400 may cover an inner wall of the connection substrate 600, but may expose an upper surface of the connection substrate 600. The molding layer 400 may include an insulating material. As an example, the molding layer 400 may include epoxy molding compound (EMC) or the like.

An upper redistribution layer 700 may be provided on the molding layer 400. The upper redistribution layer 700 may be disposed on the upper surface of the molding layer 400. The molding layer 400 may fill a space between the lower redistribution layer 100 and the upper redistribution layer 700.

The upper redistribution layer 700 may include upper insulating layers 711, 712, 713, and 714, an outer insulating layer 720, line patterns 750, via structures 770, upper patterns 781, 782, and upper pads 790, a marking structure 800, and a dummy marking pattern 930.

The upper insulating layers 711, 712, 713, and 714 may include first to fourth upper insulating layers 711, 712, 713, and 714. The number of upper insulating layers 711, 712, 713, and 714 may not be limited thereto. For example, the number of upper insulating layers 711, 712, 713, and 714 may be 3 or less, or 5 or more.

The first to fourth upper insulating layers 711, 712, 713, and 714 may be sequentially stacked in the third direction D3. The second upper insulating layer 712 may be disposed on the first upper insulating layer 711. The third upper insulating layer 713 may be disposed on the second upper insulating layer 712. The fourth upper insulating layer 714 may be disposed on the third upper insulating layer 713.

The outer insulating layer 720 may be provided on the upper insulating layers 711, 712, 713, and 714. The outer insulating layer 720 may be disposed on an upper surface of the fourth upper insulating layer 714.

The first to fourth upper insulating layers 711, 712, 713, and 714 and the outer insulating layer 720 may include an insulating material. The first to fourth upper insulating layers 711, 712, 713, and 714 and the outer insulating layer 720 may include an organic material such as a photo-imageable dielectric (PID) material. The photo-imageable dielectric material may include, for example, at least one of photosensitive polyimide, polybenzoxazole, phenol-based polymer, and benzocyclobutene-based polymer. The first to fourth upper insulating layers 711, 712, 713, and 714 and the outer insulating layer 720 may be transparent.

The line patterns 750, the via structures 770, the upper patterns 781, 782, the marking structure 800, and the dummy marking pattern 930 may be conductive patterns which are disposed within the upper insulating layers 711, 712, 713, 714 and the outer insulating layer 720.

The line patterns 750 and the via structures 770 may be provided in the upper insulating layers 711, 712, 713, and 714. The line patterns 750 and via structures 770 may be surrounded by upper insulating layers 711, 712, 713, and 714. The line patterns 750 may be disposed on the first upper insulating layer 711 or the second upper insulating layer 712. The line pattern 750 on the first upper insulating layer 711 may be surrounded by the second upper insulating layer 712. The line pattern 750 on the second upper insulating layer 712 may be covered by the third upper insulating layer 713.

The via structures 770 may be disposed on the second upper insulating layer 712. The via structure 770 may include a via portion for vertical connection and line portions for horizontal connection on the via portion. The via portion of the via structure 770 may be surrounded by the second upper insulating layer 712. The line portion of the via structure 770 may be surrounded by the third upper insulating layer 713. The via structure 770 may be disposed on the line pattern 750 on the first upper insulating layer 711. The via structure 770 may be in contact with an upper surface of the line pattern 750 on the first upper insulating layer 711. The via portion of the via structure 770 may connect the line portion of the via structure 770 and the line pattern 750 on the first upper insulating layer 711.

The upper patterns 781 and 782 may be surrounded by first to third upper insulating layers 711, 712, and 713. The upper patterns 781 and 782 may include a first upper pattern 781 and a second upper pattern 782. The second upper pattern 782 may be disposed on the first upper pattern 781. The first upper pattern 781 may be disposed in the first upper insulating layer 711 and the second upper insulating layer 712. The second upper pattern 782 may be disposed in the second upper insulating layer 712 and the third upper insulating layer 713. Each of the first and second upper patterns 781 and 782 may include a via portion for vertical connection and a line portion for horizontal connection.

The first upper patterns 781 may be conductive patterns exposed below the upper redistribution layer 700. The first upper patterns 781 may be exposed through the first upper insulating layer 711. The via portion of the first upper pattern 781 may be surrounded by the first upper insulating layer 711. The line portion of the first upper pattern 781 may be surrounded by the second upper insulating layer 712. The first upper pattern 781 may connect the second upper pattern 782 and the third connection pad 633.

The via portion of the second upper pattern 782 may be surrounded by the second upper insulating layer 712. The line portion of the second upper pattern 782 may be surrounded by the third upper insulating layer 713. The upper pad 790 may be provided on the second upper pattern 782. The upper pad 790 may be in contact with an upper surface of the second upper pattern 782. The upper pad 790 may include a conductive material. As an example, the upper pad 790 may include gold (Au) or the like. The second upper pattern 782 may be connected to the upper pad 790.

The line patterns 750, via structures 770, and upper patterns 781 and 782 may include a conductive material. As an example, the line patterns 750, via structures 770, and upper patterns 781 and 782 may include copper (Cu) or the like.

The marking structure 800 may be surrounded by upper insulating layers 711, 712, 711, and 714 and an outer insulating layer 720. The marking structure 800 may be provided on the semiconductor chip 200. The marking structure 800 may overlap the semiconductor chip 200.

The marking structure 800 may include a lower marking pattern 810, a marking via 820 on the lower marking pattern 810, and an upper marking pattern 830 on the marking via 820.

The lower marking pattern 810 may be disposed on the first upper insulating layer 711. The lower marking pattern 810 may be in contact with the upper surface of the first upper insulating layer 711. The lower marking pattern 810 may be surrounded by the second upper insulating layer 712. An upper surface 810_U of the lower marking pattern 810 may be in contact with the marking via 820. The lower marking pattern 810 may include a conductive material.

The marking via 820 may be surrounded by second and third upper insulating layers 712 and 713. The marking via 820 may penetrate the third upper insulating layer 713. The marking via 820 may connect the lower marking pattern 810 and the upper marking pattern 830. The marking via 820 may include a plurality of marking vias 820. A width of the marking via 820 may become smaller as a level thereof decreases. The marking via 820 may include a conductive material.

The upper marking pattern 830 may be disposed on the third upper insulating layer 713. The upper marking pattern 830 may be in contact with an upper surface of the third upper insulating layer 713. The upper marking pattern 830 may be surrounded by a fourth upper insulating layer 714 and an outer insulating layer 720. A sidewall of the upper marking pattern 830 may be in contact with the fourth upper insulating layer 714. The upper marking pattern 830 may include a conductive material. As an example, the upper marking pattern 830 may include at least one of copper (Cu), nickel (Ni), gold (Au), titanium (Ti), and aluminum (Al) or alloys thereof.

The upper marking pattern 830 may include a first conductive pattern 831, a second conductive pattern 832 on the first conductive pattern 831, and a third conductive pattern 833 on the second conductive pattern 832.

The first conductive pattern 831 of the upper marking pattern 830 may be connected to the marking via 820. The first conductive pattern 831 may include the same material as the lower marking pattern 810 and the marking via 820. For example, the first conductive pattern 831, the lower marking pattern 810, and the marking via 820 may include copper (Cu) or the like.

The second conductive pattern 832 of the upper marking pattern 830 may be disposed on the first conductive pattern 831. The second conductive pattern 832 may be exposed by a trench TR, which will be described later. The second conductive pattern 832 may include a first upper surface 832_U1 exposed by the trench TR, which will be described later, and a second upper surface 832_U2 in contact with the third conductive pattern 833. A thickness of the second conductive pattern 832 in the third direction D3 may be smaller than a thickness of the first conductive pattern 831 in the third direction D3.

The third conductive pattern 833 of the upper marking pattern 830 may be disposed on the second upper surface 832_U2 of the second conductive pattern 832. The upper surface of the third conductive pattern 833 may be in contact with the outer insulating layer 720. The third conductive pattern 833 and the outer insulating layer 720 may define a trench TR. The third conductive pattern 833 may include a sidewall 833_S that defines a sidewall of the trench TR. The outer insulating layer 720 may include a first inner wall 720_IS1 that defines a sidewall of the trench TR. The sidewall 833_S of the third conductive pattern 833 may be coplanar with the first inner wall 720_IS1 of the outer insulating layer 720. Referring to FIG. 1A, the first upper surface 832_U1 of the second conductive pattern 832 exposed through the trench TR may represent a letter or symbol. A thickness of the third conductive pattern 833 in the third direction D3 may be smaller than a thickness of the first conductive pattern 831 in the third direction D3.

An upper surface of the fourth upper insulating layer 714 may be placed at a higher level than the first and second upper surfaces 832_U1 and 832_U2 of the second conductive pattern 832. The upper surface of the fourth upper insulating layer 714 may be coplanar with the upper surface of the third conductive pattern 833.

The first to third conductive patterns 831, 832, and 833 of the upper marking pattern 830 may include different materials. As an example, the first to third conductive patterns 831, 832, and 833 of the upper marking pattern 830 may include different metals. For example, the first conductive pattern 831 may include copper (Cu), the second conductive pattern 832 may include nickel (Ni), and the third conductive pattern 833 may include gold (Au), however, other combinations of metals/materials may be used without departing from the inventive concepts.

The third upper insulating layer 713, fourth upper insulating layer 714, and outer insulating layer 720 may define a peripheral hole PH. The third upper insulating layer 713 may include an inner wall 713_IS that defines a side wall of the peripheral hole PH. The fourth upper insulating layer 714 may include an inner side wall 714_IS that defines a side wall of the peripheral hole PH. The outer insulating layer 720 may include a second inner side wall 720_IS2 that defines a side wall of the peripheral hole PH. The inner wall 713_IS of the third upper insulating layer 713, the inner wall 714_IS of the fourth upper insulating layer 714, and the second inner wall 720_IS2 of the outer insulating layer 720 may be coplanar. The upper surface 790_U of the upper pad 790 may be exposed through the peripheral hole PH.

A dummy marking pattern 930 may be provided on one end of the semiconductor package. From the perspective of FIG. 1A, the dummy marking pattern 930 may be disposed on the outermost side of the semiconductor package. The dummy marking pattern 930 may be disposed on the third upper insulating layer 713. The dummy marking pattern 930 may be surrounded by the third upper insulating layer 713, the fourth upper insulating layer 714, and the outer insulating layer 720. The dummy marking pattern 930 may be exposed through an outer wall 713_OS of the third upper insulating layer 713 and an outer wall 720_OS of the outer insulating layer 720.

The dummy marking pattern 930 may include a first dummy pattern 931, a second dummy pattern 932 on the first dummy pattern 931, and a third dummy pattern 933 on the second dummy pattern 932. The first to third dummy patterns 931, 932, and 933 may include a conductive material.

The first dummy pattern 931 of the dummy marking pattern 930 may include the same material as the first conductive pattern 831 of the upper marking pattern 830. The second dummy pattern 932 of the dummy marking pattern 930 may include the same material as the second conductive pattern 832 of the upper marking pattern 830. The third dummy pattern 933 of the dummy marking pattern 930 may include the same material as the third conductive pattern 833 of the upper marking pattern 830.

A level of the dummy marking pattern 930 may be the same as a level of the upper marking pattern 830. A level of the first dummy pattern 931 may be the same as a level of the first conductive pattern 831. A level of the second dummy pattern 932 may be the same as a level of the second conductive pattern 832. A level of the third dummy pattern 933 may be the same as a level of the third conductive pattern 833.

A thickness of the second dummy pattern 932 in the third direction D3 may be smaller than a thickness of the first dummy pattern 931 in the third direction D3. A thickness of the third dummy pattern 933 in the third direction D3 may be smaller than the thickness of the first dummy pattern 931 in the third direction D3. The outer insulating layer 720 may cover an upper surface of the third dummy pattern 933.

The first to third dummy patterns 931, 932, and 933 of the dummy marking pattern 930 may include different materials. As an example, the first to third dummy patterns 931, 932, and 933 of the dummy marking pattern 930 may include different metals. For example, the first dummy pattern 931 may include copper (Cu), the second dummy pattern 932 may include nickel (Ni), and the third dummy pattern 933 may include gold (Au), however, other combinations of metals/materials may be used without departing from the inventive concepts.

An outer wall 930_OS of the dummy marking pattern 930 may include an outer wall 931_OS of the first dummy pattern 931, an outer wall 932_OS of the second dummy pattern 932, and an outer wall 933_OS of the third dummy pattern 933. The outer wall 713_OS of the third upper insulating layer 713, the outer wall 720_OS of the outer insulating layer 720, the outer wall 931_OS of the first dummy pattern 931, the outer wall 932_OS of the second dummy pattern 932, and the outer wall 933_OS of the third dummy pattern 933 may be coplanar.

The dummy marking pattern 930 may define a dummy hole DH. The dummy marking pattern 930 may include an inner side wall 930_IS of the dummy marking pattern 930 that defines a side wall of the dummy hole DH. The inner wall 930_IS of the dummy marking pattern 930 may include an inner wall 931_IS of the first dummy pattern 931, an inner wall 932_IS of the second dummy pattern 932, and an inner wall 933_IS of the third dummy pattern 933. The fourth upper insulating layer 714 may fill the dummy hole DH. The fourth upper insulating layer 714 may penetrate the dummy hole DH. The inner wall 931_IS of the first dummy pattern 931, the inner wall 932_IS of the second dummy pattern 932, and the inner wall 933_IS of the third dummy pattern 933 may be in contact with the fourth upper insulating layer 714. The inner wall 931_IS of the first dummy pattern 931, the inner wall 932_IS of the second dummy pattern 932, and the inner wall 933_IS of the third dummy pattern 933 may be coplanar.

In a semiconductor package according to some example embodiments, the upper marking pattern 830 may include first to third conductive patterns 831, 832, and 833 made of different materials. The uppermost third conductive pattern 833 and the outer insulating layer 720 may be partially removed to form a trench TR defined by the outer insulating layer 720 and the third conductive pattern 833. The second conductive pattern 832 may be exposed through the trench TR to generate a difference from the third conductive pattern 833 around the second conductive pattern 832, thereby improving visibility of the upper marking patterns 830.

A semiconductor package according to some example embodiments may include a marking via 820 connecting the lower marking pattern 810 and the upper marking pattern 830. The marking via 820 may be provided, and heat may move inside the upper redistribution layer 700 through the marking via 820 to improve heat dissipation characteristics, thereby improving electrical characteristics of the semiconductor package.

A semiconductor package according to some example embodiments may include a dummy marking pattern 930 defining a dummy hole DH at one end of the semiconductor package. The dummy marking pattern 930 defining the dummy hole DH may be provided to exhaust gas generated during the manufacturing process of the semiconductor package through the dummy hole DH, thereby improving adhesion between the upper insulating layers 711, 712, 713, and 714. The dummy marking pattern 930 may be provided at one end of the semiconductor package to prevent warpage of semiconductor package. Accordingly, durability of the semiconductor package may be improved.

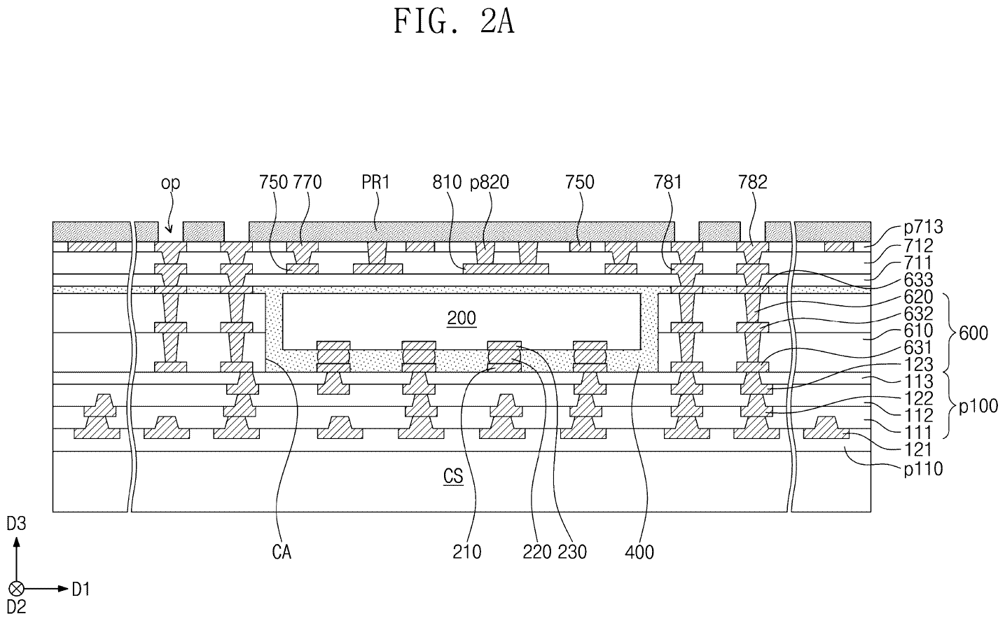

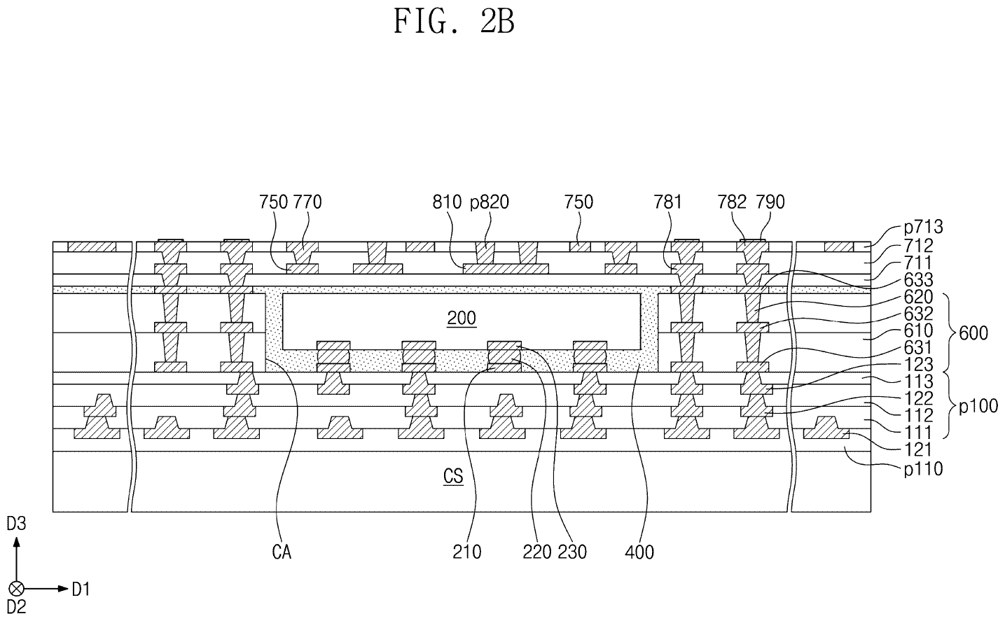

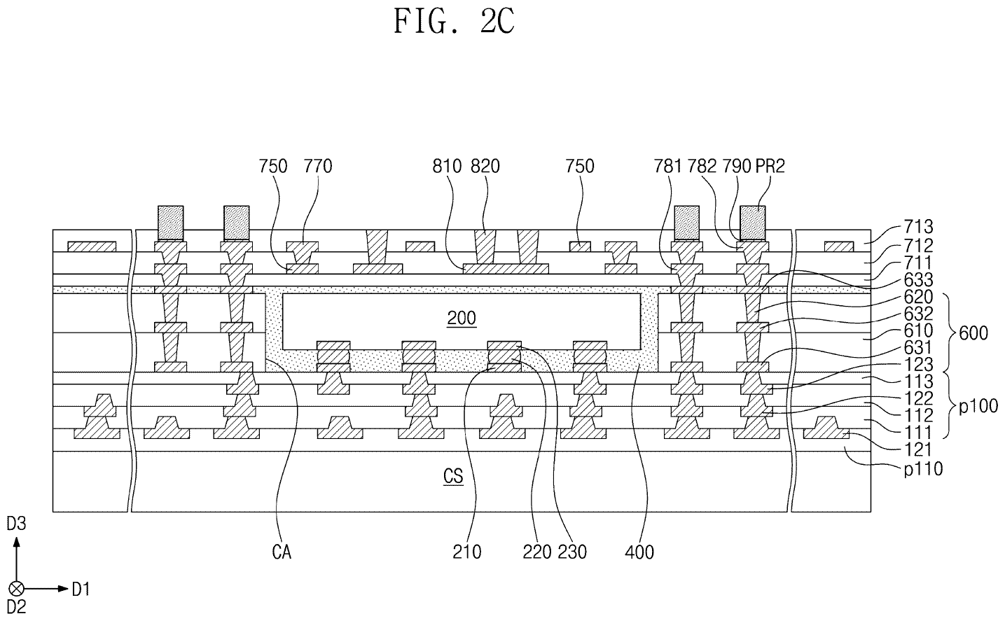

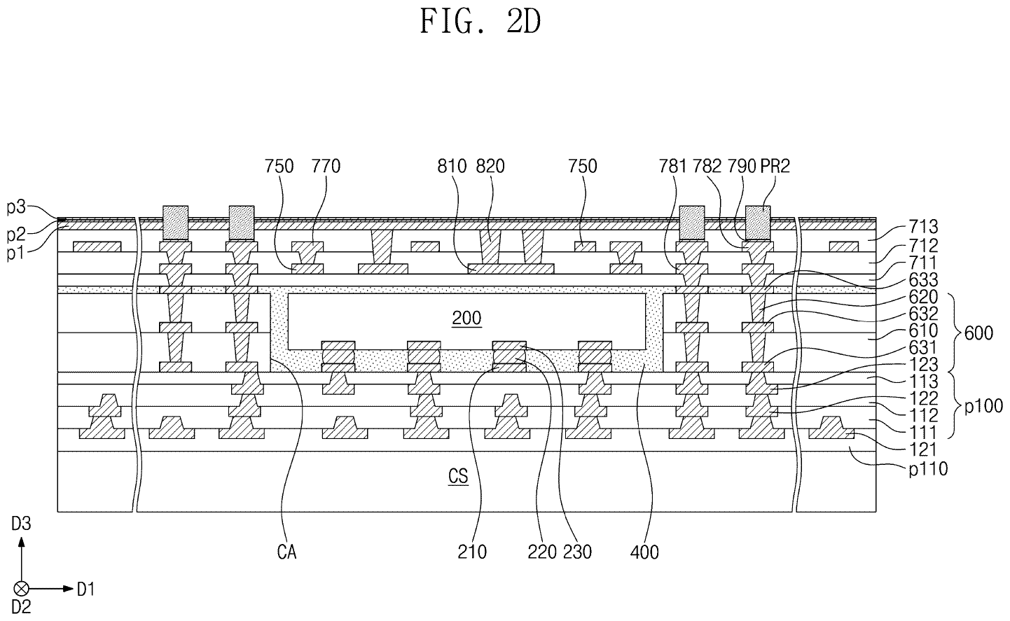

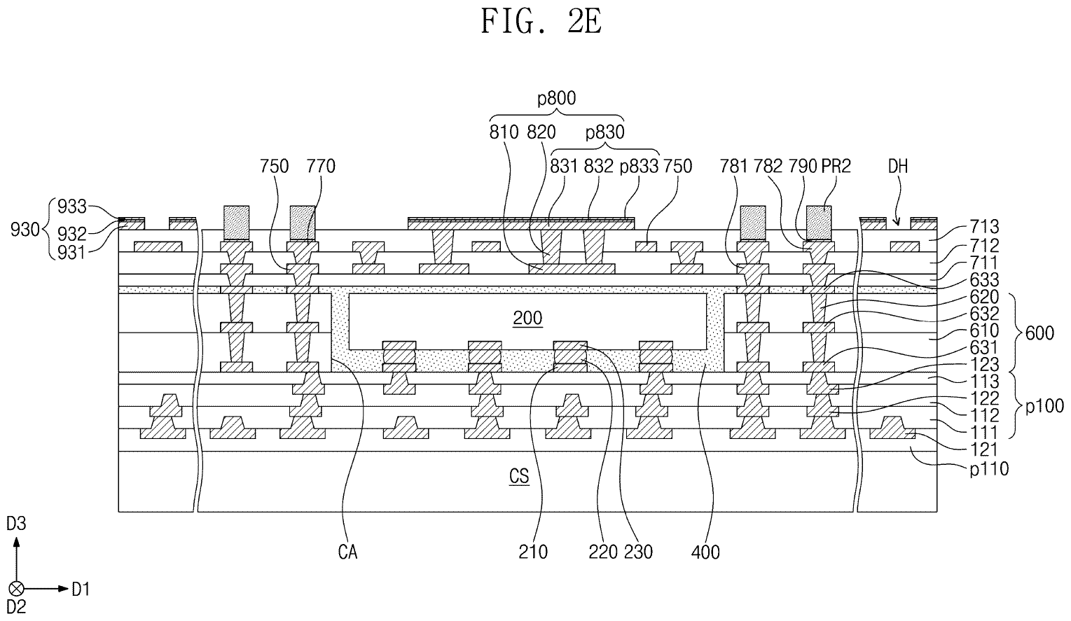

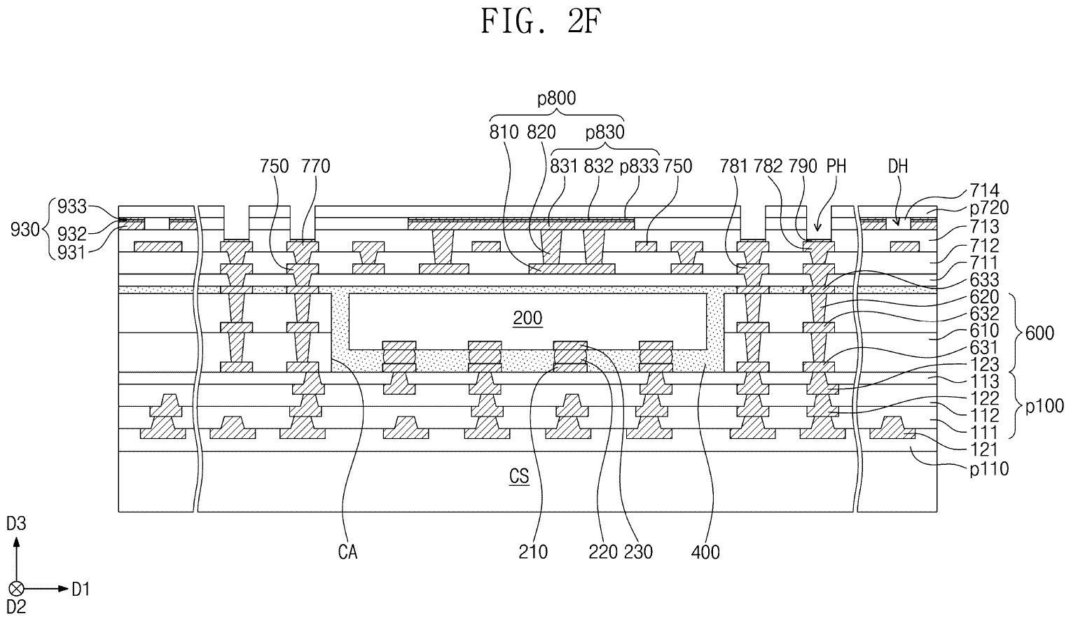

FIGS. 2A, 2B, 2C, 2D, 2E, and 2F are cross-sectional views for explaining a method of manufacturing a semiconductor package according to some example embodiments.

Referring to FIG. 2A, a carrier substrate CS, a preliminary lower redistribution layer p100 on the carrier substrate CS, a semiconductor chip 200 on the preliminary lower redistribution layer p100, and a connection substrate 600 surrounding the semiconductor chip 200, and a molding layer 400 covering the semiconductor chip 200 and the connection substrate 600.

The preliminary lower redistribution layer p100 may include a preliminary lower insulating layer p110, a first lower insulating layer 111 on the preliminary lower insulating layer p110, a second lower insulating layer 112 on the first lower insulating layer 111, a third lower insulating layer 113 on the second lower insulating layer 112, a first lower pattern 121 on the preliminary lower insulating layer p110, a second lower pattern 122 on the first lower pattern 121, and a third lower pattern 123 on the second lower pattern 122.

The preliminary lower insulating layer p110 may cover a lower surface of the first lower pattern 121. The preliminary lower insulating layer p110 may be in contact with an upper surface of the carrier substrate CS.

A first upper insulating layer 711 on the molding layer 400, a second upper insulating layer 712 on the first upper insulating layer 711, a third preliminary upper insulating layer p713 on the second upper insulating layer 712, and a photoresist layer PR 1 on the third preliminary insulating layer 711 may be formed. The second upper insulating layer 712 and the third preliminary upper insulating layer p713 may surround the second upper pattern 782, the line pattern 750, and the preliminary marking via p820. The first photoresist layer PR1 may include an opening op exposing an upper surface of the third preliminary upper insulating layer p713. For example, the opening op of the first photoresist layer PR1 may be formed through a photolithography process.

Referring to FIG. 2B, an upper pad 790 may be formed. The upper pad 790 may be formed within the opening op. The upper pad 790 may be formed on an upper surface of the second upper pattern 782 exposed through the opening op. After the upper pad 790 is formed on the upper surface of the upper pattern 782, the first photoresist layer PR1 may be removed.

Referring to FIG. 2C, a second photoresist layer PR2 may be formed on the upper pad 790. After forming the second photoresist layer PR2, an insulating material (not shown) may be formed on the third preliminary upper insulating layer p713. An insulating material (not shown) may not be formed on the upper pad 790 by the second photoresist layer PR2. The insulating material (not shown) on the preliminary marking via p820 may be partially removed to expose the preliminary marking via p820. The insulating material (not shown) on the preliminary marking via p820 may be partially removed to expose the third upper insulating layer 713. An empty space formed by removing the portion of the insulating material (not shown) may be filled with a conductive material to form the marking via 820. An upper surface of the marking via 820 may be exposed by the third upper insulating layer 713.

Referring to FIG. 2D, a first preliminary conductive layer p1 may be formed. The first preliminary conductive layer p1 may not be formed on the upper pad 790 by the second photoresist layer PR2. The first preliminary conductive layer p1 may be formed on the third upper insulating layer 713.

A second preliminary conductive layer p2 may be formed on the first preliminary conductive layer p1 and a third preliminary conductive layer p3 may be formed on the second preliminary conductive layer p2. A thickness of the first preliminary conductive layer p1 in the third direction D3 may be greater than a thickness of each of the second and third preliminary conductive layers p2 and p3 in the third direction D3. The first to third preliminary conductive layers p1, p2, and p3 may include different materials. For example, the first to third preliminary conductive layers p1, p2, and p3 may include different metals.

Referring to FIG. 2E, a portion of each of the first to third preliminary conductive layers p1, p2, and p3 may be removed to form a preliminary marking structure p800 and a dummy marking pattern 930.

The preliminary marking structure p800 may include a lower marking pattern 810, a marking via 820 on the lower marking pattern 810, and a preliminary upper marking pattern p830 on the marking via 820. The preliminary upper marking pattern p830 may include a first conductive pattern 831, a second conductive pattern 832 on the first conductive pattern 831, and a third preliminary conductive pattern p833 on the second conductive pattern 832. The third preliminary conductive pattern p833 may completely cover an upper surface of the second conductive pattern 832.

A portion of each of the first to third preliminary conductive layers p1, p2, and p3 may be removed to expose an inner wall 930_IS of the dummy marking pattern 930. The exposed inner wall 930_IS of the dummy marking pattern 930 may define a dummy hole DH. An upper surface of the third upper insulating layer 713 may be exposed through the dummy hole DH.

Referring to FIG. 2F, a fourth upper insulating layer 714 on the third upper insulating layer 713 and a preliminary outer insulating layer p720 on the fourth upper insulating layer 714 may be formed. The fourth upper insulating layer 714 and the preliminary outer insulating layer p720 may not be formed on the upper pad 790 by the second photoresist layer PR2. The fourth upper insulating layer 714 may be formed in the dummy hole DH. A preliminary outer insulating layer p720 may be formed on the preliminary marking structure p800 and the dummy marking pattern 930. The preliminary outer insulating layer p720 may be in contact with an upper surface of the fourth upper insulating layer 714, an upper surface of the preliminary upper marking pattern p830 of the preliminary marking structure p800, and an upper surface of the dummy marking pattern p930. After forming the preliminary outer insulating layer p720, the second photoresist layer PR2 on the upper pad 790 may be removed. The second photoresist layer PR2 may be removed to form a peripheral hole PH.

Referring again to FIGS. 1B and 1C, a portion of the third preliminary conductive pattern p833 and a portion of the preliminary outer insulating layer p720 of the preliminary upper marking pattern p830 may be removed. The portion of the third preliminary conductive pattern p833 may be removed to form the third conductive pattern 833 of the upper marking pattern 830. A portion of the third preliminary conductive pattern p833 may be removed to form a sidewall 833_S of the third conductive pattern 833. A portion of the preliminary outer insulating layer p720 may be removed to form the outer insulating layer 720. A portion of the preliminary outer insulating layer p720 may be removed to form the first inner wall 720_IS1 of the outer insulating layer 720. A sidewall 833_S of the third conductive pattern 833 and a first inner wall 720_IS1 of the outer insulating layer 720 may be formed to define a trench TR. A portion of the third preliminary conductive pattern p833 and a portion of the preliminary outer insulating layer p720 may be removed to expose a first upper surface 832_U1 of the second conductive pattern 832 of the upper marking pattern 830.

The carrier substrate CS and the preliminary lower insulating layer p110 may be removed. The carrier substrate CS and the preliminary lower insulating layer p110 may be removed to form the lower redistribution layer 100. The carrier substrate CS and the preliminary lower insulating layer p110 may be removed to expose the first lower pattern 121. A solder ball 300 may be formed on a lower surface of the first lower pattern 121.

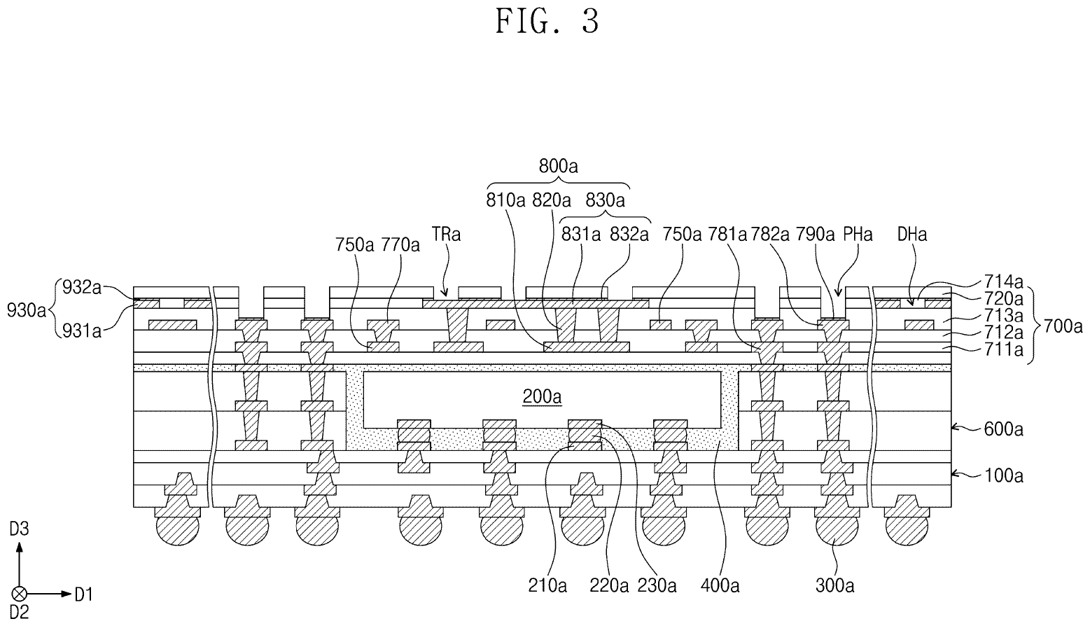

FIG. 3 is a cross-sectional view of a semiconductor package according to some example embodiments.

Referring to FIG. 3, solder balls 300a, a lower redistribution layer 100a on the solder balls 300a, a semiconductor chip 200a on the lower redistribution layer 100a, a connection substrate 600a surrounding the semiconductor chip 200a, a molding layer 400a covering the semiconductor chip 200a and the connection substrate 600a, and an upper redistribution layer 700a on the molding layer 400a may be provided.

The upper redistribution layer 700a may include first to fourth upper insulating layers 711a, 712a, 713a, and 714a, an outer insulating layer 720a, a marking structure 800a, and a dummy marking pattern 930a.

The marking structure 800a may include a lower marking pattern 810a, a marking via 820a on the lower marking pattern 810a, and an upper marking pattern 830a on the marking via 820a. The upper marking pattern 830a may include a first conductive pattern 831a and a second conductive pattern 832a on the first conductive pattern 831a.

The second conductive pattern 832a and the outer insulating layer 720a may define a trench TRa. The trench TRa may be defined by an inner wall of the outer insulating layer 720a and a sidewall of the second conductive pattern 832a. An upper surface of the first conductive pattern 831a may be exposed through the trench TRa.

The first conductive pattern 831a and the second conductive pattern 832a may include different materials. For example, the first conductive pattern 831a and the second conductive pattern 832a may include different metals. For example, the first conductive pattern 831a may include copper (Cu), and the second conductive pattern 832a may include gold (Au) or the like. A thickness of the second conductive pattern 832a in the third direction D3 may be smaller than a thickness of the first conductive pattern 831a in the third direction D3. An upper surface of the second conductive pattern 832a may be in contact with the outer insulating layer 720a.

The dummy marking pattern 930a may include a first dummy pattern 931a and a second dummy pattern 932a on the first dummy pattern 931a. A dummy hole DHa may be defined by the dummy marking pattern 930a. A sidewall of the dummy hole DHa may be defined by an inner wall of the first dummy pattern 931a and an inner wall of the second dummy pattern 932a. A level of the first dummy pattern 931a of the dummy marking pattern 930a may be the same as a level of the first conductive pattern 831a of the upper marking pattern 830a. A level of the second dummy pattern 932a of the dummy marking pattern 930a may be the same as a level of the second conductive pattern 832a of the upper marking pattern 830a.

The number of conductive patterns 831a and 832a of the upper marking pattern 830a and the number of dummy patterns 931a and 932a of the dummy marking pattern 930a may not be limited thereto. For example, the number of conductive patterns 831a and 832a of the upper marking pattern 830a and the number of dummy patterns 931a and 932a of the dummy marking pattern 930a may be four or more.

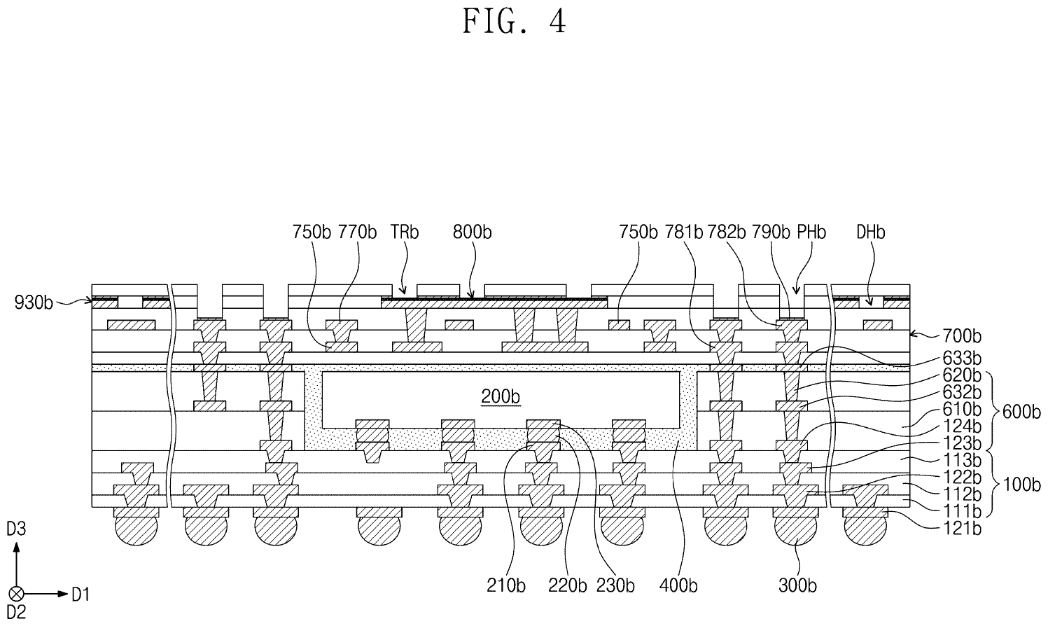

FIG. 4 is a cross-sectional view of a semiconductor package according to some example embodiments.

Referring to FIG. 4, solder balls 300b, a lower redistribution layer 100b on the solder balls 300b, a semiconductor chip 200b on the lower redistribution layer 100b, a connection substrate 600b surrounding the semiconductor chip 200b, a molding layer 400b covering the semiconductor chip 200b and the connection substrate 600b, and an upper redistribution layer 700b on the molding layer 400b may be provided.

The lower redistribution layer 100b may include lower insulating layers 111b, 112b, and 113b and lower patterns 121b, 122b, 123b, and 124b.

The connection substrate 600b may include a connection insulating layer 610b, connection vias 620b, and first and second connection pads 632b and 633b.

The upper redistribution layer 700b may include first and second upper vias 781b and 782b and upper pads 790b.

The lower insulating layers 111b, 112b, and 113b may include first to third lower insulating layers 111b, 112b, and 113b. The first to third lower insulating layers 111b, 112b, and 113b may be sequentially stacked in the third direction D3.

The lower patterns 121b, 122b, 123b, and 124b may include first to fourth lower patterns 121b, 122b, 123b, and 124b. The first lower pattern 121b may be disposed on a lower surface of the lower redistribution layer 100b. The second to fourth lower patterns 122b, 123b, and 124b may be conductive patterns disposed inside the lower insulating layers 111b, 112b, and 113b.

The first lower pattern 121b may be a line portion for horizontal connection. The first lower pattern 121b may be in contact with a lower surface of the first lower insulating layer 111b. The first lower pattern 121b may be in contact with the solder ball 300b. Each of the second to fourth lower patterns 122b, 123b, and 124b may include a via portion for vertical connection and a line portion for horizontal connection on the via portion. The via portion of the second lower pattern 122b may be surrounded by the first lower insulating layer 111b. The line portion of the second lower pattern 122b may be surrounded by the second lower insulating layer 112b. The via portion of the third lower pattern 123b may be surrounded by the second lower insulating layer 112b. The line portion of the third lower pattern 123b may be surrounded by the third lower insulating layer 113b. The via portion of the fourth lower pattern 124b may be surrounded by the third lower insulating layer 113b. The line portion of the fourth lower pattern 124b may be disposed on the upper surface of the third lower insulating layer 113.

The second lower pattern 122b may connect the first lower pattern 121b and the third lower pattern 123b. The third lower pattern 123b may connect the second lower pattern 122b and the fourth lower pattern 124b. The fourth lower pattern 124b may be connected to the connection via 620b of the connection substrate 600b.

The connection via 620b may connect the fourth lower pattern 124b and the first connection pad 632b. The connection via 620b may connect the first connection pad 632b and the second connection pad 633b. The second connection pad 633b may be connected to the first upper pattern 781b.

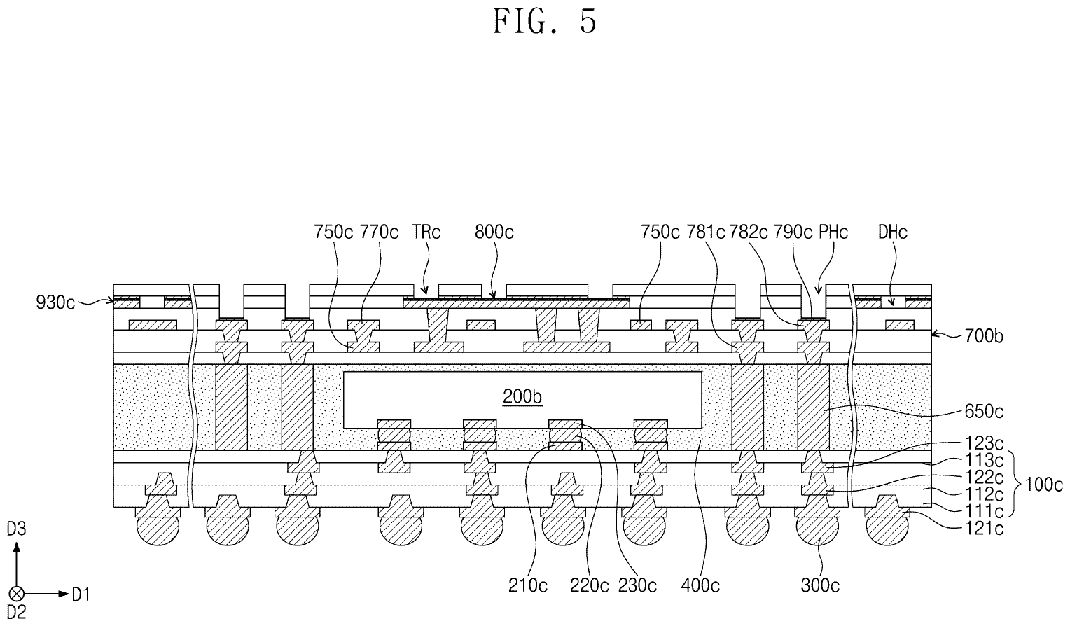

FIG. 5 is a cross-sectional view of a semiconductor package according to some example embodiments.

Referring to FIG. 5, solder balls 300c, a lower redistribution layer 100c on the solder balls 300c, a semiconductor chip 200c on the lower redistribution layer 100c, a molding layer 400c covering the semiconductor chip 200c, and an upper redistribution layer 700c on the molding layer 400c may be provided.

The lower redistribution layer 100c may include first to third lower insulating layers 111c, 112c, and 113c and first to third lower patterns 121c, 122c, and 123c.

The upper redistribution layer 700c may include first and second upper patterns 781c and 782c.

Conductive structures 650c may be provided on the lower redistribution layer 100c. The conductive structures 650c may penetrate the molding layer 400c. The conductive structures 650c may be surrounded by the molding layer 400c. A lower surface of the conductive structure 650c may be in contact with an upper surface of the third lower pattern 123c of the lower redistribution layer 100c. An upper surface of the conductive structure 650c may be in contact with a lower surface of the first upper pattern 781c of the upper redistribution layer 700c. The conductive structure 650c may electrically connect the lower redistribution layer 100c and the upper redistribution layer 700c. The conductive structures 650c may be spaced apart from the semiconductor chip 200c in the first direction D1 or the second direction D2. The conductive structures 650c may be spaced apart from each other. The conductive structures 650c may surround the semiconductor chip 200.

In the semiconductor package according to some example embodiments of the inventive concepts, the second conductive pattern exposed through the trench may have a different material from that of the third conductive pattern around the second conductive pattern, thereby improving the visibility thereof.

In the semiconductor package according to some example embodiments of the inventive concepts, the heat may move inside the upper redistribution layer through the marking via connecting the lower marking pattern and the upper marking pattern, thereby the electrical characteristics thereof.

The semiconductor package according to some example embodiments of the inventive concepts may include the dummy marking pattern defining the dummy hole to prevent or reduce warpage, thereby improving the durability thereof.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A semiconductor package comprising:
a semiconductor chip; and
an upper redistribution layer including a marking structure on the semiconductor chip, an upper insulating layer surrounding the marking structure, and an outer insulating layer on the upper insulating layer,
the marking structure including
a lower marking pattern;
a marking via on the lower marking pattern; and
an upper marking pattern on the marking via,
the upper marking pattern including a first conductive pattern on the marking via and a second conductive pattern on the first conductive pattern, and
the second conductive pattern being exposed by a trench defined by the outer insulating layer.

2. The semiconductor package of claim 1, wherein
the upper marking pattern includes a third conductive pattern on the second conductive pattern, and
an upper surface of the third conductive pattern is in contact with the outer insulating layer.

3. The semiconductor package of claim 2, wherein the first conductive pattern, the second conductive pattern, and the third conductive pattern include different materials.

4. The semiconductor package of claim 3, wherein
the first conductive pattern includes copper (Cu),
the second conductive pattern includes nickel (Ni), and
the third conductive pattern includes gold (Au).

5. The semiconductor package of claim 1, wherein the marking via includes a plurality of marking vias.

6. The semiconductor package of claim 2, wherein an inner wall of the outer insulating layer and a side wall of the third conductive pattern are coplanar.

7. The semiconductor package of claim 2, wherein the trench is defined by an inner wall of the outer insulating layer and a sidewall of the third conductive pattern.

8. The semiconductor package of claim 2, wherein the second conductive pattern includes a first upper surface exposed by the trench and a second upper surface in contact with the third conductive pattern.

9. The semiconductor package of claim 1, wherein
the upper insulating layer includes a first insulating layer, a second insulating layer on the first insulating layer, a third insulating layer on the second insulating layer, and a fourth insulating layer on the third insulating layer, and
an upper surface of the fourth insulating layer is in contact with the outer insulating layer.

10. The semiconductor package of claim 9, wherein the upper redistribution layer includes an upper pattern in the second and third insulating layers and a peripheral pad on the upper pattern.

11. The semiconductor package of claim 10, wherein an upper surface of the peripheral pad is exposed by a peripheral hole defined by the outer insulating layer, the second insulating layer, and the third insulating layer.

12. The semiconductor package of claim 9, wherein the upper surface of the fourth insulating layer is at a higher level than an upper surface of the second conductive pattern.

13. A semiconductor package comprising:
a semiconductor chip; and
an upper redistribution layer including a marking structure on the semiconductor chip, an upper insulating layer surrounding the marking structure, and an outer insulating layer on the upper insulating layer,
the marking structure including a first conductive pattern, a second conductive pattern on the first conductive pattern, and a third conductive pattern on the second conductive pattern,
an upper surface of the second conductive pattern being exposed by a trench defined by the outer insulating layer, and
the first conductive pattern and the second conductive pattern include different materials.

14. The semiconductor package of claim 13, wherein a thickness of the third conductive pattern is smaller than a thickness of the first conductive pattern.

15. The semiconductor package of claim 13, wherein the upper redistribution layer includes a dummy marking pattern exposed through an outer wall of the upper insulating layer.

16. The semiconductor package of claim 15, wherein
an inner wall of the dummy marking pattern defines a dummy hole, and
the upper insulating layer fills the dummy hole.

17. The semiconductor package of claim 15, wherein an outer wall of the upper insulating layer, an outer wall of the dummy marking pattern, and an outer wall of the outer insulating layer are coplanar.

18. The semiconductor package of claim 13, wherein the outer insulating layer is transparent.

19. A semiconductor package comprising:
a lower redistribution layer;
a semiconductor chip on the lower redistribution layer;
a core layer surrounding the semiconductor chip on the lower redistribution layer and including a core via; and
an upper redistribution substrate on the semiconductor chip,
the upper redistribution substrate including
a marking structure overlapping the semiconductor chip;
an upper insulating layer surrounding the marking structure;
a dummy marking pattern exposed through an outer wall of the upper insulating layer; and
an outer insulating layer on the marking structure, the upper insulating layer, and the dummy marking pattern,
the marking structure including a lower marking pattern, a marking via on the lower marking pattern, and an upper marking pattern on the marking via, and
a level of the dummy marking pattern being a same level as a level of the upper marking pattern.

20. The semiconductor package of claim 19, wherein
the upper marking pattern includes a first conductive pattern and a second conductive pattern on the first conductive pattern, and
the first conductive pattern and the second conductive pattern include different materials.
